(19) United States
(12) Patent Application Publication
(10) Pub. No.: US 2007/0119567 A1
(43) Pub. Date: May 31, 2007

(54) HEAT DISSIPATION DEVICE

(75) Inventors: CHIN-WEN YEH, Tu-Cheng,Taipei Hsien (TW); SHU-HO LIN, Tu-Cheng,Taipei Hsien (TW); Zhi-Ya Yang, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,227

(22) Filed: Jul. 13, 2006

(30) Foreign Application Priority Data
Nov. 25, 2005 (TW) 94141488

(51) Int. Cl. H05K 7/20

(52) U.S. Cl. 165/80.3; 165/121; 361/699

(57) ABSTRACT

A heat dissipation device includes a heat sink, a cooling fan having a frame arranged on the heat sink, and a fan holder disposed between the heat sink and the cooling fan. The fan holder includes a square shaped frame defining an opening therein. A pair of flexible fasteners extend upwardly from a pair of opposite sides of the frame and abut a pair of opposite side edges of the frame of the cooling fan. At least a clamping arm extends upwardly from one of the other pair of opposite sides of the frame of the fan holder and abuts one of the other pair of opposite sides of the frame of the cooling fan.

### FIELD OF THE INVENTION

The present invention generally relates to a heat dissipation device, and more particularly to a heat dissipation device for use with electronic elements.

### DESCRIPTION OF RELATED ART

With the development of large scale integrated circuit technology in the information industry, personal computers are becoming more and more popular. As we know, the central processing unit (CPU) is the core unit of a computer system, and accordingly plays an important role in maintaining the integrity and performance of the computer system. With the increasing demand for higher processing power in computers, the CPUs are now operating at higher speeds and thus generate larger amounts of heat. The heat must be quickly and efficiently removed from the CPU; otherwise, the temperature of the CPU will increase until above its critical operating temperature, thus affecting the performance and reliability of the computer. Therefore, newer microprocessors with enhanced functions and a more complex design require an increased heat dissipation so as to timely dissipate the heat generated thereby. Generally, the heat is dissipated by a heat dissipation assembly being maintained in thermal contact with the CPU.

Conventionally, the heat dissipation assembly includes a heat sink and a fan mounted on the heat sink. The heat sink commonly includes a base and a plurality of fins thereon. The base thermally contacts with a heat source element and transfers the heat generated by the heat source element to the fins. A forced airflow generated by the fan flows over the fins to enhance heat dissipation of the heat sink, and to ensure a steady operation for the heat source element.

At present, the fan is mounted to the heat sink, usually by means of screws. However, in this method, a mounting tool such as a screw driver is required to mount the fan to or detach the fan from the heat sink, which can be cumbersome and time-consuming.

Locking the fan by means of a fan holder is another method of combining the fan to the heat sink. The fan defines a groove therein and the fan holder has a hook thereon. The fan is attached to the heat sink by the hook of the fan holder engaging in the groove of the fan. However, in this method, the fan is mounted to the fan holder in a self-locking manner where the fan is permanently secured to the fan holder and cannot be detached therefrom for replacement or repair.

Accordingly, it is desirable to provide a heat dissipation device wherein at least one of the aforementioned disadvantages may be overcome or at least alleviated.

### SUMMARY OF THE INVENTION

A heat dissipation device in accordance with a preferred embodiment of the present invention comprises a heat sink, a cooling fan mounted on the heat sink, and a fan holder disposed between the heat sink and the cooling fan. The fan holder comprises a square shaped frame defining an opening therein. At least one flexible fastener is set on each of a pair of opposite sides of the frame; the at least one flexible fastener is configured to have an elasticity allowing it to deform outwardly. At least one clamping arm is set on one of the other pair of opposite sides of the frame.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views, in which:

FIG. 1 is an assembled, isometric view of a heat dissipation device in accordance with an embodiment of the present invention;

FIG. 2 is an exploded view of the heat dissipation device of FIG. 1;

FIG. 3 is an assembled, isometric view of a heat dissipation device in accordance with another embodiment of the present invention; and

FIG. 4 is an exploded view of the heat dissipation device of FIG. 3.

### DETAILED DESCRIPTION OF THE INVENTION

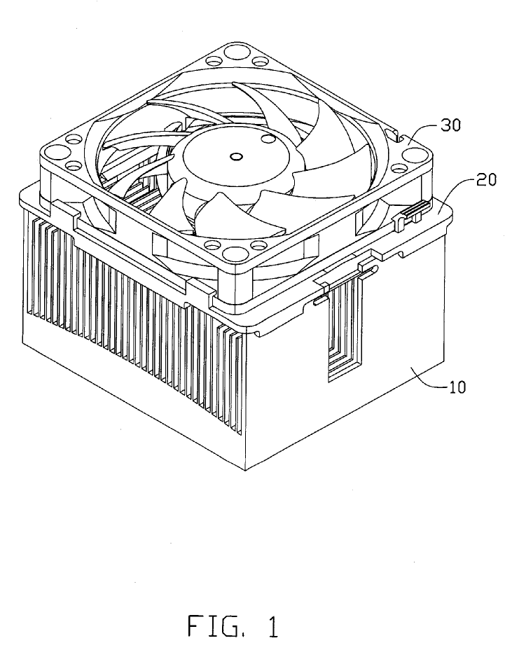

Referring to FIG. 1, a heat dissipation device in accordance with an embodiment of the present invention comprises a heat sink 10, a cooling fan 30 and a fan holder 20 arranged therebetween to mount the cooling fan 30 to the heat sink 10.

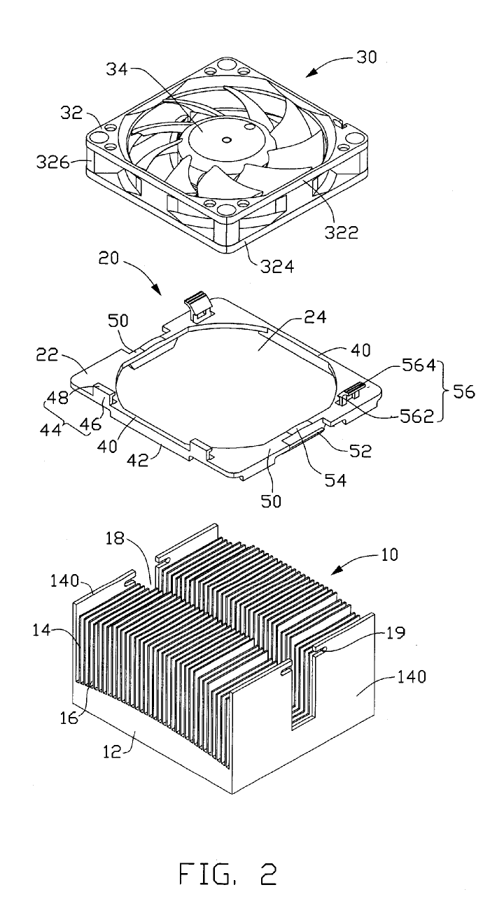

Referring to FIG. 2, the heat sink 10 comprises a base 12 and a plurality of fins 14 arranged on the base 12. The fins 14 are formed integrally with the base 12 and extend vertically upwardly from the base 12. The fins 14 are spaced apart from each other so that a channel 16 is formed between every two adjacent fins 14. A cutout (not labeled) is defined in a middle portion of each of the fins 14, so that these cutouts cooperatively form an elongated groove 18 perpendicular to the channels 16. A clip (not shown) is located in the groove 18 to attach the heat sink 10 to a heat source element (not shown) such as a central processing unit (CPU) of a computer system. Two outmost fins 140 of the heat sink 10 are higher than the main fins 14 located between the higher fins 140. A slot 19 is defined at a top portion of each of the higher fins 140 and communicates with the groove 18.

The cooling fan 30 comprises a frame 32 and a rotor 34 located therein. A square-shaped top flange 322 and a square-shaped bottom flange 324 are formed at top and bottom sides of the frame 32, respectively. Four columns 326 are formed at four corners of the frame 32 to connect the top flange 322 with the bottom flange 324.

The fan holder 20, which is disposed between the cooling fan 30 and the heat sink 10, comprises a square shaped frame 22. The frame 22 comprises a pair of first crossbeams 40 at two opposite sides thereof and a pair of second crossbeams 50 at the other two opposite sides thereof. The first and second crossbeams 40, 50 connect in series together and accordingly an opening 24 is defined in a center of the frame 22, for providing access for an airflow from the cooling fan 30 towards the heat sink 10.

An extension portion 42 is formed on each of the first crossbeams 40 extending downwardly towards the heat sink 10. An upwardly protruding, arc-shaped bulge 54 is formed at a middle portion of each of the second crossbeams 50. An engagement block 52 extends from each of the second crossbeams 50, adjacent to the bulge 54, the size and shape of the engagement block 52 corresponding to that of the slots 19. The fan holder 20 and the heat sink 10 are combined together by the blocks 52 engaging in the slots 19.

Two spaced clamping arms 44 are formed extending upwardly from two ends of one of the first crossbeams 40. Specifically, the clamping arms 44 are located near two corners of the frame 22, respectively. Each clamping arm 44 comprises a perpendicular portion 46 extending upwardly from the frame 22 and a horizontal portion 48 extending inwardly from a distal free end of the perpendicular portion 46. Thus, a receiving space (not labeled) is formed between the clamping arm 44 and the frame 22 so as to locate an outer peripheral portion of the bottom flange 324 of the fan 30.

A flexible fastener 56 is formed extending upwardly from one end of each of the second crossbeams 50 remote from the corresponding clamping arm 44. In other words, the fasteners 56 are located near the other two corners of the frame 22. The flexible fastener 56 comprises a locking portion 562 being in the form of an inner hook and a handle portion 564. The height of the locking portion 562 corresponds to that of the bottom flange 324 of the fan 30. The handle portion 564 inclines upwardly and outwardly from a distal end of the locking portion 562. In assembly, the handle portions 564 may be operated by hand. The flexible fasteners 56 are accordingly splayed outwardly due to deformation thereof so that the cooling fan 30 is fixed to the fan holder 20.

The frame 22, the clamping arms 44 and the flexible fasteners 56 are preferably made of plastic material, and are formed integrally so as to simplify the manufacturing process.

In assembly, the cooling fan 30 is disposed at a slant so that the outer peripheral portion of the bottom flange 324 can be received in the receiving spaces formed by the clamping arms 44. The handle portions 564 of the flexible fasteners 56 can be deformed outwardly, either by hand or by other means, so as to allow the cooling fan 30 to be pushed downwardly entering into engagement with the fasteners 56. After the handle portions 564 are released, the flexible fasteners 56 return to their original positions, and the locking portions 562 engage with the outer peripheral portion of the bottom flange 324 of the cooling fan 30, thereby firmly grasping the cooling fan 30 on the fan holder 20. The clamping arms 44 and the flexible fasteners 56 abut against three edges of the bottom flange 324 of the cooling fan 30, thus restricting the cooling fan 30 from movement relative to the fan holder 20. In addition, the arc-shaped bulges 54 on the frame 22 are provided to abut against a bottom face (not labeled) of the cooling fan 30 and make up assembly tolerance between the cooling fan 30 and the fan holder 20, so as to combine the cooling fan 30 and the fan holder 20 more tightly and restrict the cooling fan 30 from moving in the axial direction of the cooling fan 30. Thus, the cooling fan 30 is assembled to the fan holder 20.

Thereafter, the cooling fan 30 and the fan holder 20 are placed on the heat sink 10. The blocks 52 of fan holder 20 engage with the outmost fins 140 in the slots 19. The extension portions 42 of the fan holder 20 abut against a top surface defined by the main fins 14. Thus the assembly of the heat dissipation device is completed. In use, the heat dissipation device is mounted on the heat source element by the clip located in the groove 18.

To detach the heat dissipation device, the handle portions 564 of the flexible fasteners 56 are brought to splay outwardly so that the cooling fan 30 can be taken away from the fan holder 20.

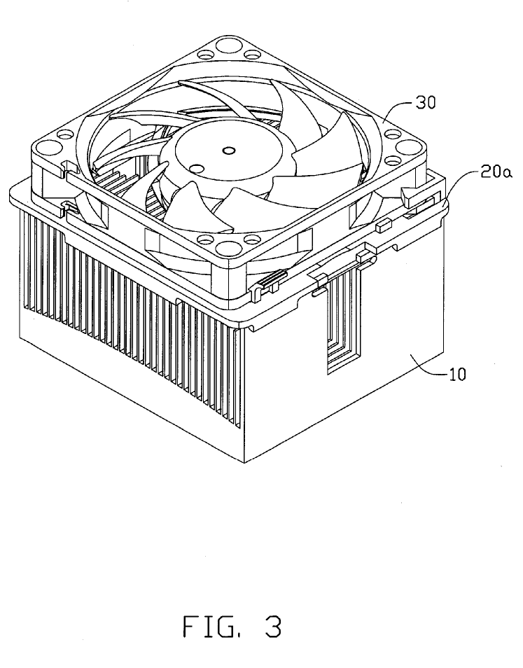

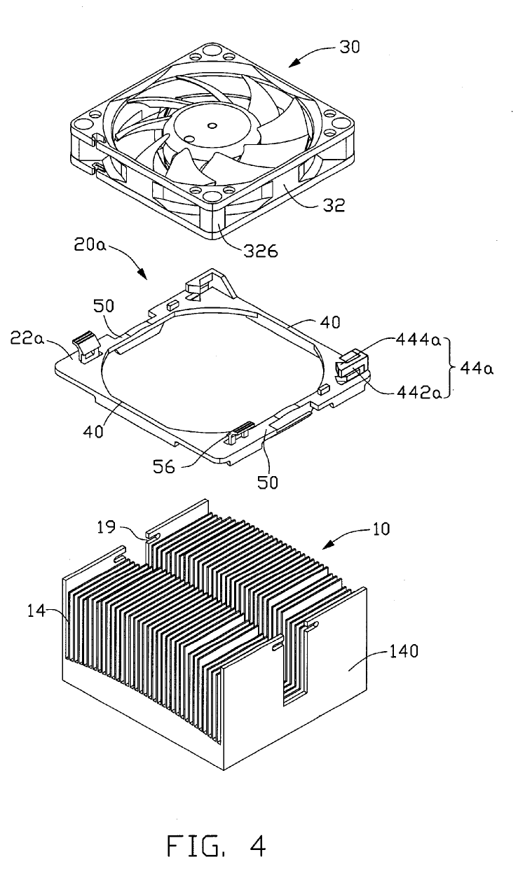

A heat dissipation device in accordance with another embodiment of the present invention is shown in FIG. 3 and FIG. 4. The heat dissipation device, as in the first embodiment of the present invention, comprises a heat sink 10, a cooling fan 30 and a fan holder 20a. The fan holder 20a comprises a pair of clamping arms 44a located near two corners of the frame 22a and a pair of flexible fasteners 56 located near the other two corners of the frame 22a. The difference is that each of the clamping arms 44a comprises a perpendicular portion (not labeled) extending upwardly from the frame 22a and a flexible finger 442a extending inwardly from a free distal end of the perpendicular portion. A hook 444a is formed at a free distal end of the flexible finger 442a. In assembly, the hook 444a catches the corresponding column 326 of the cooling fan 30, as shown in FIG. 3.

In the above embodiments, the positions and the quantities of the clamping arms 44, 44a and the flexible fasteners 56 can be changed if needed. It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A heat dissipation device, comprising:
a heat sink;
a cooling fan mounted on the heat sink; and
a fan holder disposed between the heat sink and the cooling fan, the fan holder comprising a square shaped frame defining an opening therein, at least one flexible fastener being set on each of a pair of opposite sides of the frame, the at least one flexible fastener being configured to have an elasticity to deform outwardly, at least one clamping arm being set on one of the other pair of opposite sides of the frame, the at least one flexible fastener and the at least one clamping arm engaging with the cooling fan to lock the cooling fan on the fan holder, wherein when the at least one flexible fastener is deformed outwardly, the lock between the fan and the fan holder is released.

2. The heat dissipation device of claim 1, wherein the frame of the fan holder, the at least one flexible fastener and the at least one clamping arm are formed integrally with each other.

3. The heat dissipation device of claim 1, wherein the cooling fan comprises a frame, the frame comprising a top flange and a bottom flange, the bottom flange being engaged by the at least one flexible fastener and the at least one clamping arm.

4. The heat dissipation device of claim 3, wherein the at least one flexible fastener extends upwardly and outwardly from the frame of fan holder, comprising a locking portion which abuts against the bottom flange of the cooling fan and a handle portion at a distal end of the locking portion.

5. The heat dissipation device of claim 3, wherein the at least one clamping arm comprises a perpendicular portion extending upwardly from the frame of the fan holder and a horizontal portion extending inwardly from a top end of the perpendicular portion, forming a space to locate the bottom flange of the cooling fan.

6. The heat dissipation device of claim 3, wherein the at least one clamping arm comprises a perpendicular portion extending upwardly from the frame of the fan holder, a flexible finger extending inwardly from the perpendicular portion and a hook formed at a distal end of the flexible finger.

7. The heat dissipation device of claim 6, wherein a plurality of columns is formed at corners of the cooling fan to connect the top flange with the bottom flange, and the hook catches one of the columns.

8. The heat dissipation device of claim 3, wherein a pair of opposite sides of the frame of cooling fan are sandwiched by the at least one flexible fastener, and one of another pair of opposite sides of the frame of cooling fan abuts against the at least one clamping arm.

9. The heat dissipation device of claim 1, wherein the heat sink comprises a plurality of fins, and two slots are formed in two outmost fins.

10. The heat dissipation device of claim 9, wherein a pair of blocks extend from the frame of fan holder and engage within the slots, respectively.

11. A heat dissipation device, comprising:
a heat sink;
a fan holder seated on the heat sink, the fan holder being substantially square-shaped and comprising a pair of clamping arms located at two corners thereof and a pair of flexible fasteners located at the other two corners thereof;
a cooling fan mounted to the fan holder, the clamping arms and the flexible fasteners of the fan holder grasping the cooling fan at an outer peripheral portion thereof, wherein the flexible fasteners are outwardly movable to release the grasping of the flexible fasteners on the cooling fan.

12. The heat dissipation device of claim 11, wherein the clamping arms are located at a common side of the fan holder and each of the clamping arms is in the form of a L-shaped plate.

13. The heat dissipation device of claim 11, wherein each of the flexible fasteners includes an inner hooked portion and a handle portion extending from the hooked portion.

14. The heat dissipation device of claim 11, wherein the cooling fan includes a top flange and a bottom flange opposite to the top flange, said outer peripheral portion being a peripheral edge portion of the bottom flange.

15. The heat dissipation device of claim 11, wherein the fan holder has at least an upwardly extending bulge abutting against a bottom face of the cooling fan.

16. The heat dissipation device of claim 11, wherein the heat sink has a plurality of fins with two outermost fins being higher than other fins therebetween, the outermost fins being provided with slots in upper portions thereof, the fan holder forming outwardly protruding engaging blocks, the engaging blocks engaging in the slots thereby connecting the fan holder and the heat sink together.
